(19) United States
(12) Patent Application Publication
(10) Pub. No.: US 2016/0027790 A1
(43) Pub. Date: Jan. 28, 2016

(54) Three-Dimensional Printed Memory

(71) Applicant: ChengDu HaiCun IP Technology LLC, ChengDu (CN)

(72) Inventor: Guobiao ZHANG, Corvallis, OR (US)

(21) Appl. No.: 14/875,716

(22) Filed: Oct. 6, 2015

Related U.S. Application Data
(62) Division of application No. 13/570,216, filed on Aug. 8, 2012, now abandoned.
Application No. 13/570,216 is a continuation-in-part of application No. 14/745,377, filed on Jun. 20, 2015.
Application No. 14/745,377 is a continuation-in-part of application No. 13/602,095, filed on Aug. 31, 2012, now abandoned.
(60) Provisional application No. 61/529,919, filed on Sep. 1, 2011.
(60) Provisional application No. 61/529,919, filed on Sep. 1, 2011.

(51) Int. Cl. H01L 27/112

(52) U.S. Cl. CPC H01L 27/11206

(57) ABSTRACT

As technology scales, the mask cost rises sharply. The present invention discloses a three-dimensional printed memory (3D-P). It uses shared data-masks to print data. Because a shared data-mask does not contain the mask-patterns for identical mass-contents, the share of the data-mask cost on each mass-content is significantly reduced. For mass publication, the minimum feature size of the 3D-P is preferably less than 45 nm.

### CROSS-REFERENCE TO RELATED APPLICATIONS

This application is a division of application, “Three-Dimensional Printed Memory”, application Ser. No. 13/570,216, filed Aug. 8, 2012, which relates to a provisional application, “Three-Dimensional Printed Memory”, Application Ser. No. 61/529,919, filed Sep. 1, 2011.

This application is also a continuation-in-part of application “Imprinted Memory”, application Ser. No. 14/745,377, filed Jun. 20, 2015, which is a continuation-in-part of application “Imprinted Memory”, application Ser. No. 13/602,095, filed Aug. 31, 2012, which claims benefit of a provisional application “Three-Dimensional Printed Memory”, Application Ser. No. 61/529,919, filed Sep. 1, 2011.

### BACKGROUND

1. Technical Field of the Invention

The present invention relates to the field of integrated circuit, and more particularly to mask-programmed read-only memory (mask-ROM).

2. Prior Arts

Optical discs, such as DVD and Blu-ray discs (BD), are the primary media for mass publication. The “mass” in mass publication has two-fold meanings: mass distribution of mass-contents. Each mass-content contains mass data, whose data volume is on the order of Gigabyte (GB). Examples of mass-contents include movies, video games, digital maps, music library, book library and software. In the case of movies, a VCD-format movie contains ˜0.5 GB data, a DVD-format movie contains ˜4 GB data, and a BD-format movie contains ˜20 GB data. On the other hand, mass distribution means distributing tens of thousands of copies, even millions of copies.

Optical discs are physically too large for mobile users. With a smaller physical size, semiconductor memory is more desired for mass publication to mobile users. Three-dimensional mask-programmed read-only memory (3D-MPROM) is one of these semiconductor memories. Several patents, including U.S. Pat. Nos. 5,835,396, 6,624,485, 6,794,253, 6,903,427 and 7,821,080, disclose various aspects of the 3D-MPROM. As illustrated in FIG. 1, a 3D-MPROM is a monolithic semiconductor memory. It comprises a semiconductor substrate 0 and a 3-D stack 16 stacked above. The 3-D stack 16 comprises M (M≧2) vertically stacked memory levels (e.g. 16A, 16B). Each memory level (e.g. 16A) comprises a plurality of upper address lines (e.g. 2a), lower address lines (e.g. 1a) and memory cells (e.g. 5aa). Each memory cell stores n (n≧1) bits. Memory levels (e.g. 16A, 16B) are coupled to the substrate 0 through contact vias (e.g. 1av, 1′av). The substrate circuit 0X in the substrate 0 comprises a peripheral circuit for the 3-D stack 16. Hereinafter, ×M×n 3D-MPROM denotes a 3D-MPROM comprising M memory levels with n bits-per-cell (bpc).

3D-MPROM is a diode-based cross-point memory. Each memory cell (e.g. 5aa) typically comprises a diode 3d. The diode 3d can be broadly interpreted as any device whose electrical resistance at the read voltage is lower than that when the applied voltage has a magnitude smaller than or polarity opposite to that of the read voltage. Each memory level (e.g. 16A) further comprises at least a data-coding layer (e.g. 6A). The pattern in the data-coding layer is a data-pattern and it represents the digital data stored in the data-coding layer. In this figure, the data-coding layer 6A is a blocking dielectric 3b, which blocks the current flow between the upper and lower address lines. Absence or existence of a data-opening (e.g. 6ca) in the blocking dielectric 3b indicates the state of a memory cell (e.g. 5ca). Besides the blocking dielectric 3b, the data-coding layer 6A could also comprise a resistive layer (referring to U.S. patent application Ser. No. 12/785,621) or an extra-dopant layer (referring to U.S. Pat. No. 7,821,080).

The data-patterns in the data-coding layers are printed from a data-mask set. Print, also referred to as pattern-transfer, transfers data-pattern from a data-mask to a data-coding layer. Hereinafter, “mask” can be broadly interpreted as any apparatus that carries the source image of the data to be printed. In general, an ×M×n 3D-MPROM needs M×n data-masks. For example, an ×8×2 3D-MPROM typically needs 16 (=8×2) data-masks. As technology scales below 90 nm, the mask cost rises sharply. For example, at 90 nm, a data-mask set for a ×8×2 3D-MPROM costs ˜$800 k (hereinafter, 1 k=1,000); while at 22 nm, the same data-mask set costs ˜$4,000 k.

In prior-art 3D-MPROM, a data-mask is dedicated to a single mass-content. As illustrated in FIG. 2, the data-mask 8A contains only the mask-patterns of the mass-content MC₀. Accordingly, this type of data-mask is referred to as dedicated data-mask. Note the dedicated data-mask 8A may contain many copies (in this case, 16 copies) of the MC₀ patterns. For the dedicated data-masks, the full burden of the data-mask cost is placed upon a single mass-content MC₀. As a result, the 3D-MPROM storing the mass-content MC₀ becomes very expensive. It was generally believed that the rising mask cost would make 3D-MPROM economically un-viable below 90 nm.

### Objects and Advantages

It is a principle object of the present invention to provide an economically viable 3D-MPROM suitable for mass publication.

It is a further object of the present invention to provide a method to reduce the effect of the rising mask cost on the 3D-MPROM.

In accordance with these and other objects of the present invention, a three-dimensional printed memory (3D-P) is disclosed.

### SUMMARY OF THE INVENTION

In order to reduce the effect of the rising mask cost on the 3D-MPROM, the present invention discloses a three-dimensional printed memory (3D-P). It is a type of 3D-MPROM and uses shared data-masks to print data. Because a shared data-mask does not contain the mask-patterns for identical mass-contents, the hefty data-mask cost can be shared by these mass-contents. To be more specific, the share of the data-mask cost on each mass-content is equal to the product of the mask cost per GB (C_{GB}, i.e. the mask cost for the mask area carrying 1 GB data) and the data-volume (in GB) of the mass-content. Because scaling drives up the mask data capacity (i.e. the amount of data carried on a data-mask) faster than the mask cost, scaling actually drives down C_{GB}. For example, from 90 nm to 22 nm nodes, C_{GB} is reduced from ˜$5.4 k/GB to ˜$1.7 k/GB. Accordingly, the cost component of the 3D-P from the data-masks decreases with scaling. Below 45 nm, the 3D-P cost can be lowered to a level good enough for DVD/BD replacement. In this specification, the data volume of each mass-content is on the order of GB, preferably greater than or equal to 0.5 GB.

### BRIEF DESCRIPTION OF THE DRAWINGS

FIG. 1 is a cross-sectional view of a 3D-MPROM;

FIG. 2 illustrates the mask-patterns on a dedicated data-mask from prior arts;

FIG. 3 illustrates the mask-patterns on a preferred shared data-mask;

FIG. 4 illustrates a preferred printing field on a finish 3D-P wafer;

FIG. 5 illustrates a preferred F-node data-mask;

FIG. 6 compares the mask cost and mask cost per GB (C_{GB}) for several mask generations;

FIG. 7 compares the cost components of a 3D-MPROM at different production volumes (V) for several 3D-P generations;

FIG. 8 shows the minimum production volume (Vₜₕ) for the 3D-P cost (C_{3D}) to reach the DVD/BD-replacement cost threshold (CO for several 3D-P generations.

It should be noted that all the drawings are schematic and not drawn to scale. Relative dimensions and proportions of parts of the device structures in the figures have been shown exaggerated or reduced in size for the sake of clarity and convenience in the drawings. The same reference symbols are generally used to refer to corresponding or similar features in the different embodiments.

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

In order to reduce the effect of the rising mask cost on the 3D-MPROM, the present invention discloses a three-dimensional printed memory (3D-P). It is a type of 3D-MPROM and uses shared data-masks to print data. The terminology “printed memory” is used to distinguish the “printing” feature of the 3D-MPROM.

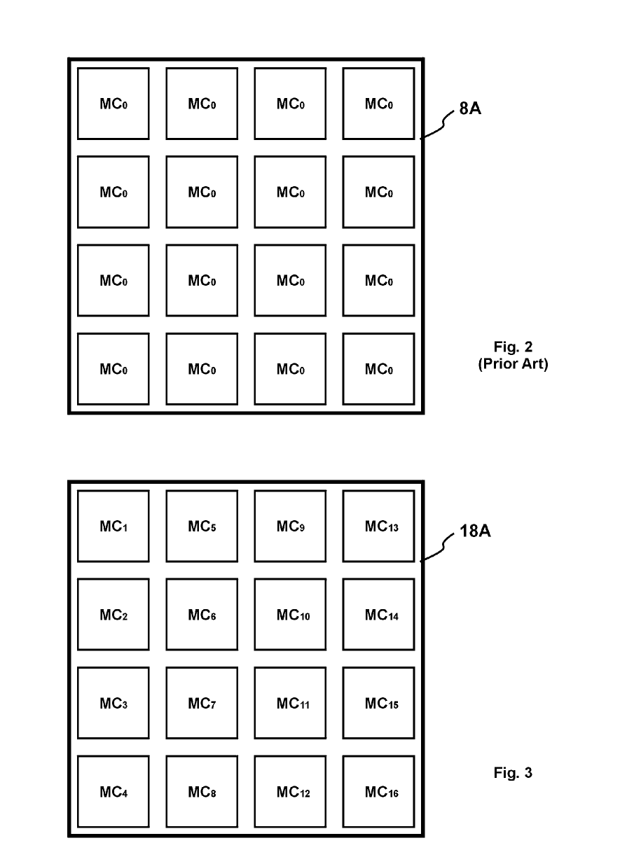

FIG. 3 illustrates the mask-patterns on a preferred shared data-mask 18A. Instead of 16 copies of a same mass-content MC₀, the mask-patterns of the shared data-mask 18A represents 16 distinct mass-contents MC₁-MC₁₆. In other words, a shared data-mask does not contain the mask-patterns for identical mass-contents. Apparently, the cost of the data-mask 18A can be shared by these 16 mass-contents. To be more specific, the share of the data-mask cost on each mass-content is equal to the product of the mask cost per GB (C_{GB}, i.e. the mask cost for the mask area carrying 1 GB data) and the data volume of the mass-content. For those skilled in the art, although the data-mask 18A in FIG. 3 carries only 16 mass-contents, a data-mask can carry a lot more mass-contents as technology scales. For example, at 22 nm node, a data-mask can carry ˜25 GB data, or ˜50 movies.

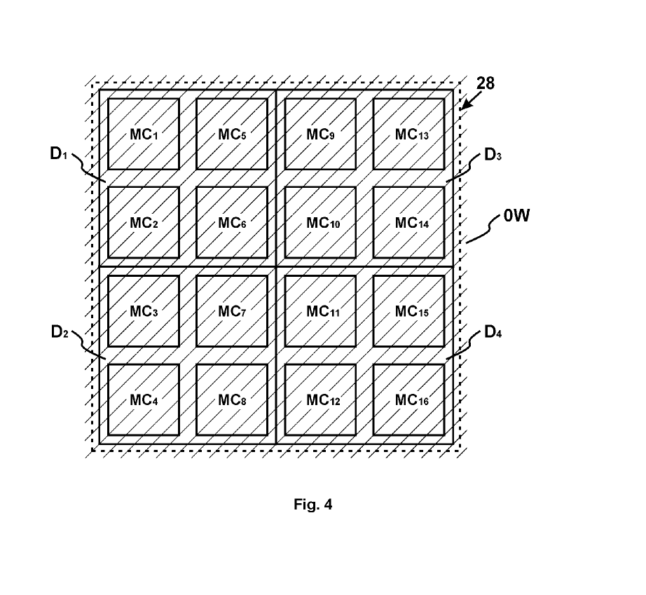

FIG. 4 illustrates a preferred printing field 28 on a finish 3D-P wafer 0W. A printing field is the wafer area that contains the patterns transferred from a whole mask in a single printing step during a step-and-repeat printing process. In photo-lithography, a printing field is an exposure field. A finished 3D-P wafer 0W comprises a plurality of repeating printing field 28. Because it is printed from the shared data-mask 18A of FIG. 3, the patterns in the printing field 28 of FIG. 4 represent 16 distinct mass contents MC₁-MC₁₆.

After dicing the finished wafer 0W, the printing field 28 is diced into four dices D1-D4, with the die D1 storing MC₁, MC₂, MC₅, MC₆; the die D2 storing MC₃, MC₄, MC₇, MC₈; the die D3 storing MC₉, MC₁₀, MC₁₃, MC₁₄; and the die D4 storing MC₁₁, MC₁₂, MC₁₅, MC₁₆. Note that these dice do not store identical mass-contents.

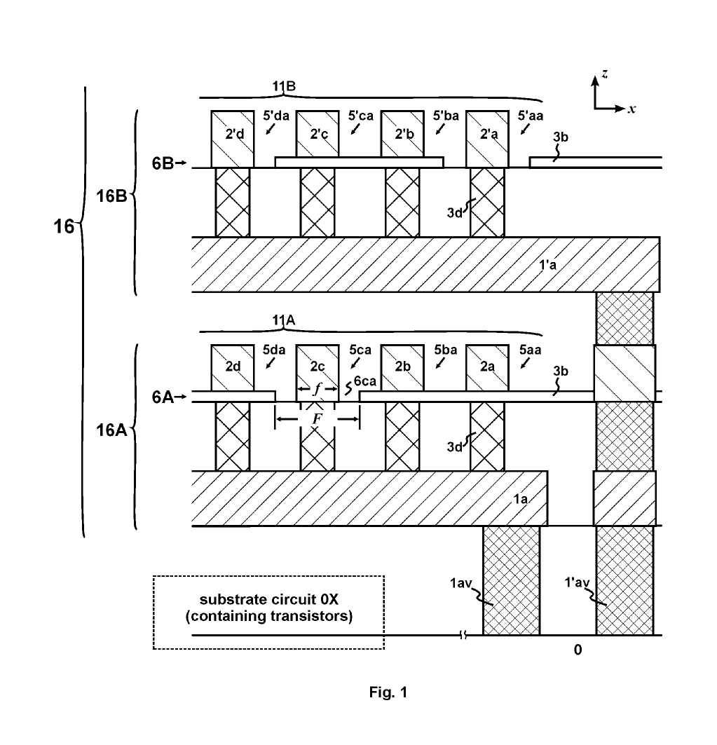

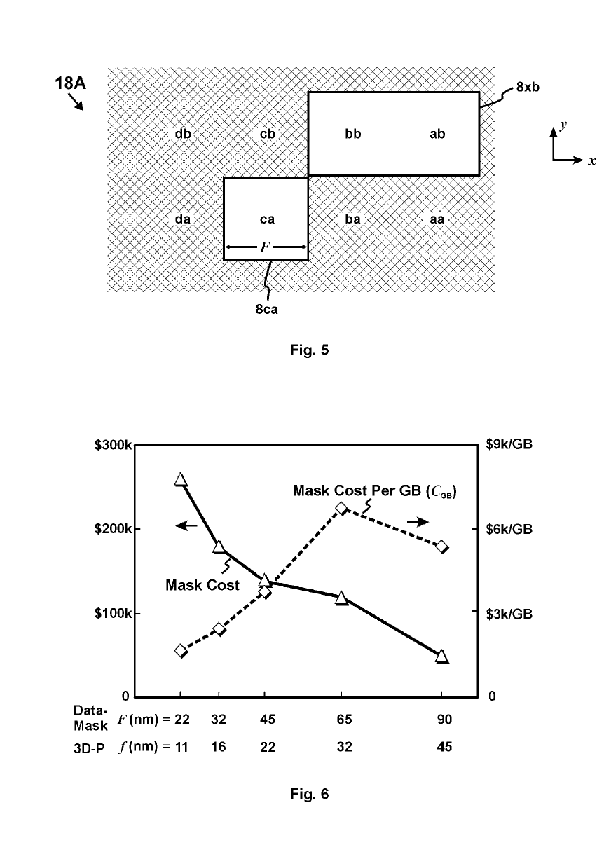

FIG. 5 illustrates a preferred F-node data-mask 18A. It is used to print data to the data-coding layer 6A of FIG. 1. The data-mask 18A is comprised of an array of mask cells “aa”-“bd”. The pattern (clear or dark) at each mask cell determines the existence or absence of data-opening at the corresponding memory cell. In this instance, the clear patterns at the mask cells “ca”, “bb”, “ab” form mask-openings 8ca, 8xb. Hereinafter, the pattern size on the data-mask is denoted by the size of its printed pattern on wafer, not its physical size on the data-mask. It is well understood that its physical size on the data-mask could be a few times (e.g. 4×) larger than that on wafer, due to image reduction in the exposure tool.

On the data-mask 18A, the minimum feature size F of the data-openings (e.g. 8ca) could be larger than, preferably twice as much as, the minimum feature size f of the 3D-P, e.g. the minimum half-pitch of its address lines (referring to U.S. Pat. No. 6,903,427). Accordingly, the data-mask 18A is also referred to as αf-mask (with α>1, preferably ˜2). In fact, the patterns in the data-coding layer in almost all types of the f-node 3D-P (including the 3D-P using blocking dielectric, resistive layer and extra-dopant layer as data-coding layer) can be printed from an αf-mask. This can significantly lower the data-mask cost. For example, for a 45 nm 3D-P, a 45 nm data-mask costs ˜$140 k, while a 90 nm data-mask costs only ˜$50 k.

Referring now to FIG. 6, the mask costs and mask cost per GB (C_{GB}) are compared for several mask generations. Here, both the minimum feature size F(=2f) of the data-mask and the minimum feature size f of the 3D-P are labeled as the x axis. When F scales from 90 nm to 22 nm, the data-mask cost increases from ˜$50 k to ˜$260 k. However, scaling also increases the mask data capacity from ˜9 GB to ˜155 GB. Overall, C_{GB} decreases from ˜$6.8 k/GB to ˜$1.7 k/GB. Note that the 90 nm mask is in mass production has a lower C_{GB}.

As an example, when the 2f-masks are used to print the movie data, the mask cost per movie ranges from ˜$27 k to ˜$7 k for a DVD-format movie (˜4 GB); or, from ˜$135 k to ˜$34 k for a BD-format movie (˜20 GB). These numbers are surprisingly lower than the numbers assumed by many skilled in the art. They are small or negligible compared with a movie's production cost.

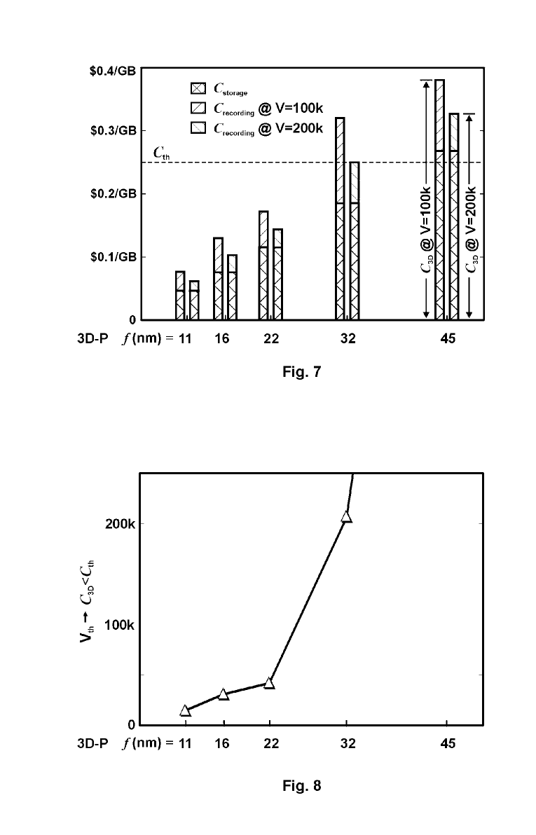

Referring now FIG. 7, the cost components of 3D-P are compared at different production volumes (V) for several 3D-P generations. Without considering copyright fees, the 3D-P cost has two components: storage cost and recording cost. At each f-node, there are two vertical bars: the bar to the left corresponds to production volume of 100 k units and the bar to the right corresponds to production volume of 200 k units. The bottom portion of the bar represents the storage cost per GB (C_{storage}) and the top portion represents the recording cost per GB (C_{recording}). The height of each bar represents the 3D-P cost per GB (C_{3D}). The values in this figure are calculated as follows:

C_{3D}=C_{storage}+C_{recording}, with

C_{storage}=C_{wafer}/D_{wafer};

C_{recording}=F_{lithography}×Cₘₐₛₖ/V.

where, C_{wafer} is the wafer cost and D_{wafer} is the effective wafer data capacity in GB; F_{lithography} is lithography cost factor, which is the ratio of the lithography cost (including mask, resist, consumables and capital expenses during the life of a mask) and the mask cost; and V is the production volume, which includes all dice whose data are printed from the data-mask.

From FIG. 7, it can be observed that the 3D-P cost decreases with scaling. This is contrary to the general belief that scaling will drive up the 3D-P cost, like it has done to the mask cost. As f scales down below 45 nm, the 3D-P cost can be lowered to <$0.25/GB. For example, a 32 nm 3D-P costs $0.25/GB at V=200 k; a 22 nm 3D-P costs $0.17/GB at V=100 k. To replace DVD/BD, the 3D-P cost should be less than the DVD/BD-replacement cost threshold (Cₜₕ). In general, Cₜₕ˜$0.25/GB. This requires the minimum feature size f of the 3D-P be less than 45 nm.

Referring now to FIG. 8, a threshold production volume (Vₜₕ) is plotted for several 3D-P generations. This Vₜₕ, once reached, will lower the 3D-P cost (C_{3D}) to Cₜₕ. Vₜₕ is an important figure of merit as it indicates the type of market an f-node 3D-P can get into. From this figure, 32 nm 3D-P, with Vₜₕ˜200 k, are only suitable for high-volume publication; while 22 nm, 16 nm and 11 nm 3D-P, with Vₜₕ˜42 k, ˜31 k, and ˜15 k, respectively, can be used for medium-volume publication.

It should be noted that medium-size or small-size contents can piggyback on mass-contents in a 3D-P. Overall, the 3D-P contents could include moving images (e.g. movies, television programs, videos, video games), still images (e.g. photos, digital maps), audio contents (e.g. music, audio books), textual contents (e.g. books), software (e.g. operating systems) and their libraries (e.g. movie library, video-game library, photo library, digital-map library, music library, book library, software library).

Finally, an overview will be given on the semiconductor memory suitable for mass publication. Three-dimensional read-only memory (3D-ROM) is an ideal media for mass publication. In the past, electrically-programmable 3D-ROM (3D-EPROM) was generally favored over 3D-MPROM. 3D-EPROM (also referred to as 3-D writable memory) uses a “writing” means to record data. However, because writing records data in a serial fashion, 3D-ERPOM has a slow write speed. For example, a 3-D one-time-programmable memory (3-D OTP) developed by Sandisk has a write speed of ˜1.5 MB/s. It needs a long time to record a movie, e.g. ˜0.5 hours for a DVD-format movie (˜4 GB), or ˜3 hours for a BD-format movie (˜20 GB). To record 1 TB data, it takes almost a week! This long recording time leads to high recording costs. The recording costs, generally overlooked in the past, make 3D-EPROM unsuitable for mass publication.

On the other hand, 3D-MPROM (or, 3D-P) uses a “printing” means to record data. Printing records data in a parallel fashion. Major printing means include photo-lithography and imprint-lithography. Both are large-scale industrial printing processes and can print a large amount of data to a large number of dice in a very short time. For example, a single exposure at 22 nm node could print up to ˜155 GB data. Intuitively, semiconductor memory, no different from the traditional paper media (e.g. books, newspapers, magazines) and plastic media (e.g. DVD, BD), prefers printing to writing for mass publication.

While illustrative embodiments have been shown and described, it would be apparent to those skilled in the art that may more modifications than that have been mentioned above are possible without departing from the inventive concepts set forth therein. For example, besides photo-mask, mask could be nanoimprint mold or nanoimprint template used in imprint-lithography. The invention, therefore, is not to be limited except in the spirit of the appended claims.

What is claimed is:

1. A method of making a three-dimensional printed memory (3D-P), comprising the steps of:
1) forming a substrate circuit on a semiconductor substrate;
2) forming a first level of address lines above said substrate;
3) forming a data-coding layer above said first level of address lines and printing a data-pattern to said data-coding layer with at least a data-mask;
4) forming a second level of address lines above said data-coding layer;
wherein, the minimum half-pitch of said address lines is less than 45 nm; and, said data-mask does not contain the mask-patterns for identical mass-contents.

2. The method according to claim 1, further comprising the steps of repeating said steps 2)-4) to form another memory level.

3. The method according to claim 1, wherein the minimum feature size of said data-mask is larger than the minimum half-pitch of said address lines.

4. The method according to claim 3, wherein the minimum feature size of said data-masks is twice the minimum half-pitch of said address lines.

5. The method according to claim 1, wherein the minimum feature size of said address lines is no larger than 32 nm.

6. The method according to claim 5, wherein the production volume of said 3D-P is greater than 200,000 units.

7. The method according to claim 1, wherein the minimum feature size of said address lines is no larger than 22 nm.

8. The method according to claim 7, wherein and the production volume of said 3D-P is greater than 42,000 units.

9. The method according to claim 1, wherein the minimum feature size of said address lines is no larger than 16 nm.

10. The method according to claim 9, wherein the production volume of said 3D-P is greater than 31,000 units.

11. The method according to claim 1, wherein the minimum feature size of said address lines is no larger than 11 nm.

12. The method according to claim 11, wherein the production volume of said 3D-P is greater than 15,000 units.

13. The method according to claim 1, wherein selected one of said mass-contents is a movie.

14. The method according to claim 1, wherein selected one of said mass-contents is a video game.

15. The method according to claim 1, wherein selected one of said mass-contents is a digital map.

16. The method according to claim 1, wherein selected one of said mass-contents is a music library.

17. The method according to claim 1, wherein selected one of said mass-contents is a book library.

18. The method according to claim 1, wherein selected one of said mass-contents is a software library.
